(19) United States
(12) Patent Application Publication
(10) Pub. No.: US 2021/0278248 A1
(43) Pub. Date: Sep. 9, 2021

(54) Magnetic Position Sensor System and Sensor Module

(71) Applicant: Vitesco Technologies Germany GmbH, Hannover (DE)

(72) Inventors: Felix Reuning, Zirndorf (DE); Heinrich Acker, Schwalbach (DE); Alex Kiess, Nürnberg (DE); Andreas Rebelein, Neunkirchen a. Sand (DE); Bernhard Schuch, Neusitz (DE)

(73) Assignee: Vitesco Technologies Germany GmbH, Hannover (DE)

(21) Appl. No.: 17/327,073

(22) Filed: May 21, 2021

Related U.S. Application Data
(63) Continuation of application No. PCT/EP2019/082230, filed on Nov. 22, 2019.

(30) Foreign Application Priority Data
Nov. 22, 2018 (DE) 10 2018 220 032.7

(51) Int. Cl. G01D 5/20; H05K 1/02; H05K 1/11; H01F 27/24; H01F 27/28

(52) U.S. Cl. CPC G01D 5/2046; H05K 1/0298; H05K 2201/10151; H01F 27/24; H01F 27/2804; H05K 1/115

(57) ABSTRACT

A magnetic position sensor system including a multilayer printed circuit board is provided. A layer includes an insulator layer and at least one copper layer. A copper layer includes at least a first conductor track and/or a second conductor track, first through-hole, second through-hole and a circuit board core, and a sensor with a soft magnetic core, an excitation coil with at least one excitation winding and a sensor coil with at least one sensor winding. The soft magnetic core is arranged in the circuit board core of the multilayer circuit board, and is surrounded by an excitation coil and a sensor coil, where an excitation winding of the excitation coil includes two first through-holes, at least in sections, and two first conductor tracks, and where a sensor winding of the sensor coil includes two second through-holes, at least in sections, and two second conductor tracks.

### CROSS-REFERENCE TO RELATED APPLICATIONS

This application claims the benefit of PCT Application PCT/EP2019/082230, filed Nov. 22, 2019, which claims priority to German Application 10 2018 220 032.7, filed Nov. 22, 2018. The disclosures of the above applications are incorporated herein by reference.

### TECHNICAL FIELD

The disclosure relates to a magnetic position sensor system and a sensor module with such a position sensor system.

### BACKGROUND

Position or distance sensors are used for example for contactless monitoring of gear selector movements in motor vehicle transmissions. A magnetic position sensor is known.

One possible example of such a sensor system is the so-called permanent magnetic linear contactless displacement sensor, or PLCD sensor for short. In a conventional PLCD sensor system, such as for detecting the position of a magnet, for example, a soft magnetic core around which coils are wound is applied to a circuit board.

For evaluating the sensor system, a corresponding integrated circuit with additional external wiring is required.

A relatively large installation space is usually necessary for this. The corresponding construction technology is complex and costly. In addition, extra protective measures such as potting or an extra coating of the system against environmental influences are usually necessary.

### SUMMARY

The disclosure provides a magnetic position sensor system that is compact, reliable and simple and inexpensive to manufacture.

The magnetic position sensor system includes a multilayer circuit board. A layer of the multilayer circuit board includes an insulator layer, such as a so-called prepreg layer, and at least one copper layer. A copper layer includes at least a first conductor track and/or a second conductor track. The multilayer circuit board also includes first through-hole, second through-hole and a circuit board core, and a sensor with a soft magnetic core, an excitation coil with at least one excitation winding and a sensor coil with at least one sensor winding.

Circuit boards conventionally consist of one or more substrate layers made of glass-fiber reinforced, cured epoxy resin, which are copper-clad on one or both sides to form electrically conducting structures, such as conductor tracks. In the case of multilayer circuit boards, one or more of these substrate layers are pressed by way of prepregs and, in some cases, also additionally with copper foils. The substrate layers and prepregs form electrically insulating substrate layers of the multilayer circuit board.

The isolated conductor tracks between electrically insulating substrate layers are electrically connected to one another by metallized through-hole in the multilayer circuit board.

According to the disclosure, the soft magnetic core is arranged in the circuit board core of the multilayer circuit board, and is surrounded by an excitation coil and a sensor coil, where an excitation winding of the excitation coil includes two first through-holes, at least in sections, and two first conductor tracks, and where a sensor winding of the sensor coil includes two second through-holes, at least sections thereof, and two second conductor tracks.

The soft magnetic core is advantageously embedded directly in the circuit board. A coil winding of the excitation coil or of the sensor coil around the core is respectively realized by a first and second conductor track on a copper layer, which in turn are electrically connected with the aid of corresponding sections of the first and second through-hole.

This leads to a reduction in the height of the installation space normally required. This construction concept makes the system more resistant to harmful environmental influences and the minimization of the production processes reduces manufacturing costs.

In one example of the position sensor system, the excitation coil and the sensor coil are arranged on different layers of the multilayer circuit board.

In a further example of the position sensor system, the excitation coil and the sensor coil are arranged on the same layer of the multilayer circuit board, whereby the number of layers, and thus the overall height, of the position sensor system can be kept small, depending on the application.

In a further development of the position sensor system, an excitation winding includes two first through-holes and two first conductor tracks on the outer copper layer, and a sensor winding includes two second through-holes and two second conductor tracks on the outer copper layer.

In a further example of the position sensor system, the respective lengths of the multilayer circuit board, the excitation coil, the sensor coil and the core are divided into outer and inner sections.

The lengths may assume different values within the maximum value of the multilayer circuit board, that is to say that the respective lengths of the excitation coil and the sensor coil may differ.

In developments of the position sensor system, the windings of the excitation coil and/or of the sensor coil may be distributed uniformly over the corresponding length, where the spacing of the individual windings is the same. In some cases, the spacing of the individual windings may also vary over the corresponding length.

In a further example of the position sensor system, the windings of the excitation coil and/or of the sensor coil may be distributed non-uniformly over the corresponding length. In this case, the windings of the excitation coil and/or of the sensor coil may be arranged predominantly on one outer section or on both outer sections, where the outer sections are then electrically conductively connected to one another on the core side, for example by a straight conductor piece. It would also be conceivable that the windings of the excitation coil and/or of the sensor coil are arranged predominantly in the inner section, in particular in the area of the soft magnetic core.

In a further example of the position sensor system, the excitation coil encloses the sensor coil in sections or entirely, or vice versa.

In some examples, depending on the application, excitation windings of an excitation coil or sensor windings of a sensor coil including conductor tracks and through-hole, or corresponding sections of the through-hole, may be arranged symmetrically or asymmetrically in relation to the soft magnetic core, for example with respect to the layers of the multilayer circuit board and/or with respect to the through-hole.

In a further example of the position sensor system, the soft magnetic core, such as like the entire position sensor system, is of a strip-shaped form, where the position of a magnet moving in an axis parallel to the multilayer circuit board can be detected.

Another aspect of the disclosure provides a sensor module that is compact, reliable, simple and inexpensive to manufacture. The sensor module includes at least one position sensor system according to the disclosure and at least parts of an electronic evaluating unit, where the electronic evaluating unit may be arranged at least partially in the multilayer circuit board, which represents a compact and secure example of a sensor module.

Alternatively, the electronic evaluating unit or parts thereof may also be arranged on any outer surface of the multilayer circuit board, depending on requirements.

In a further example, the electronic evaluating unit may be arranged at least partially outside the multilayer circuit board.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic representation of a position sensor system in sectional view,

FIG. 2 shows a schematic three-dimensional representation of a position sensor system according to FIG. 1,

FIG. 3 shows a schematic representation of a sensor module with a position sensor system according to FIG. 1,

FIG. 4 shows a schematic representation like FIG. 1 with additional layers,

FIGS. 5 to 7 show different schematic representations according to FIG. 4 in longitudinal section.

Like reference symbols in the various drawings indicate like elements.

### DETAILED DESCRIPTION

FIG. 1 shows a schematic representation of a magnetic position sensor system 1 in a cross-sectional view, where here the cross section is rectangular. The magnetic position sensor system 1 includes a multilayer circuit board 2, with an outer copper layer 3 on the upper side and the underside of the multilayer circuit board 2, with first outer conductor tracks 3a and second outer conductor tracks 3b respectively on the corresponding outer copper layer 3 on the upper side and the underside of the multilayer circuit board 2. Furthermore, the multilayer circuit board 2 in this example includes two prepreg layers 5 as an insulator layer and two inner copper layers 4, which enclose a circuit board core 6. In this case, a copper layer 4 respectively includes first inner conductor tracks 4a and second inner conductor tracks 4b.

The copper layers 3, 4, the outer conductor tracks 3a, 3b and the inner conductor tracks 4a, 4b are electrically connected to one another by first and second through-holes 7, 8 or by corresponding sections thereof.

Furthermore, the magnetic position sensor system 1 includes a sensor with a soft magnetic core 11, which is arranged entirely in the circuit board core 6 of the multilayer circuit board 2. The core 11 is essentially concentrically surrounded by an excitation coil with at least one excitation winding and a sensor coil with at least one sensor winding.

In FIG. 1, an excitation winding includes a first outer conductor track 3a on the outer copper layer 3 of the upper side and a first outer conductor track 3a on the outer copper layer 3 of the underside of the multilayer circuit board 2. These conductor tracks 3a are each electrically connected to one another by two first through-holes 7 to form the excitation winding 3a, 7, 3a, 7. This excitation winding 3a, 7, 3a, 7 is closest to the core 11 in FIG. 1.

A sensor winding includes a second outer conductor track 3b on the outer copper layer 3 of the upper side and a second outer conductor track 3b on the outer copper layer 3 of the underside of the multilayer circuit board 2. These second outer conductor tracks 3b are each electrically connected to one another by two second through-holes 8 to form the sensor winding 3b, 8, 3b, 8. This sensor winding 3b, 8, 3b, 8 in FIG. 1 encloses the excitation winding with the core 11.

Alternatively, the excitation winding may also enclose the sensor winding.

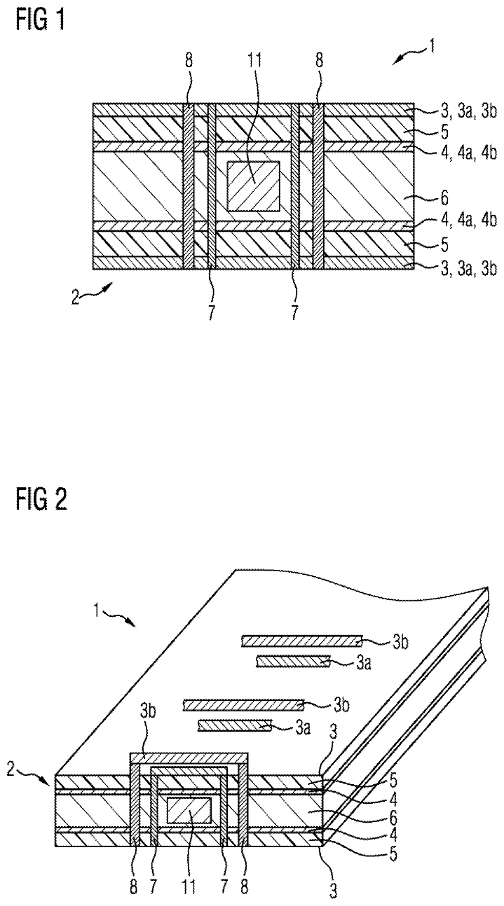

FIG. 2 shows a schematic three-dimensional representation of a position sensor system 1 according to FIG. 1. The multilayer circuit board 2 and the core 11 embedded therein are of a strip-shaped form. A position sensor system 1 is shown, with three excitation windings 3a, 7, 3a, 7 and three sensor windings 3b, 8, 3b, 8, only the outer conductor tracks 3a, 3b on the outer copper layer 3 of the upper side of the multilayer circuit board 2 being shown.

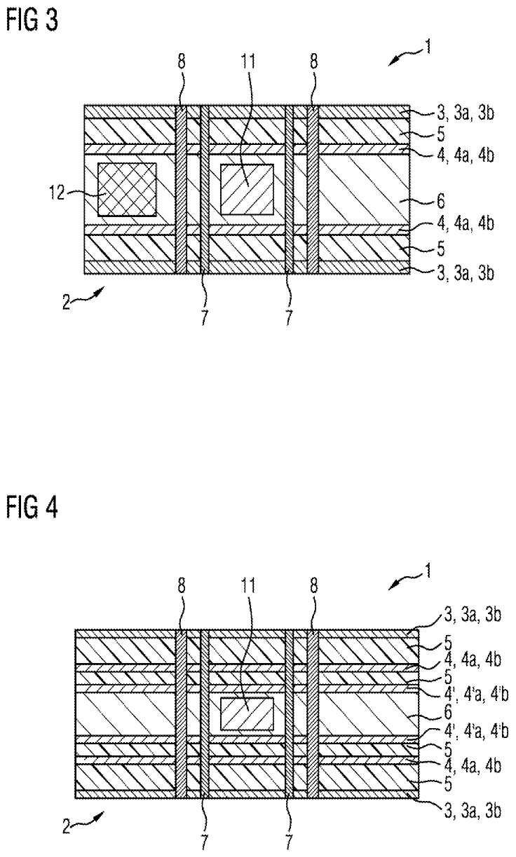

FIG. 3 shows a schematic representation of a sensor module. The sensor module includes a position sensor system 1 according to FIG. 1 and a corresponding electronic evaluating unit 12, or a part thereof, arranged in the circuit board core 6 of the multilayer circuit board 2, for processing the signals from the position sensor system 1. The electronic evaluating unit 12 may also be arranged on or outside the multilayer circuit board 2.

The sensor module may similarly include more than one sensor and/or more than one electronic evaluating unit 12.

FIG. 4 shows a schematic representation of a position sensor system 1 like FIG. 1 with only two additional layers, each including a further inner copper layer 4′ and a further insulator layer 5. In this case, an inner copper layer 4′ respectively includes, for example, first inner conductor tracks 4′a and second inner conductor tracks 4′b.

The outer conductor tracks 3a, 3b and the inner conductor tracks 4a, 4b, 4′a, 4′b are electrically connected to one another respectively by first and second through-holes 7, 8, or by corresponding sections thereof, with the formation of corresponding windings.

An excitation winding of an excitation coil or a sensor winding of a sensor coil includes conductor tracks 3a, 3b, 4a, 4b, 4′a, 4′b and through-holes 7, 8, or corresponding sections of the through-holes 7, 8, may be arranged symmetrically or asymmetrically in relation to the soft magnetic core 11, for example, with respect to the layers of the multilayer circuit board 2 and/or with respect to the through-holes 7, 8.

Examples of a symmetrical arrangement of a winding are:
4′a,7,4′a, 7;
4′b, 8,4′b, 8;
4a, 7, 4a, 7;
4b, 8, 4b, 8;
3a, 7, 3a, 7;
3b, 8, 3b, 8;

Examples of an asymmetrical arrangement of a winding with respect to the layer are:
4′a, 7, 4a, 7;
3a, 7, 4′a, 7;

Examples of an asymmetrical arrangement of a winding with respect to the through-holes 7, 8 are:
4′a, 7, 4b, 8;
3b, 8, 4′a, 7;

where, in the specified combinations, the first-mentioned conductor track with respect to the core 11 is arranged above and the second-mentioned conductor track with respect to the core 11 is arranged below the core 11; and the first-mentioned through-hole with respect to the core 11 is arranged on the left and the second-mentioned through-hole with respect to the core 11 is arranged on the right of the core 11.

As already mentioned, the corresponding through-holes 7, 8 are only involved in sections in windings having inner conductor tracks.

As likewise already mentioned, the excitation coil and the sensor coil may also be interchanged, depending on the application.

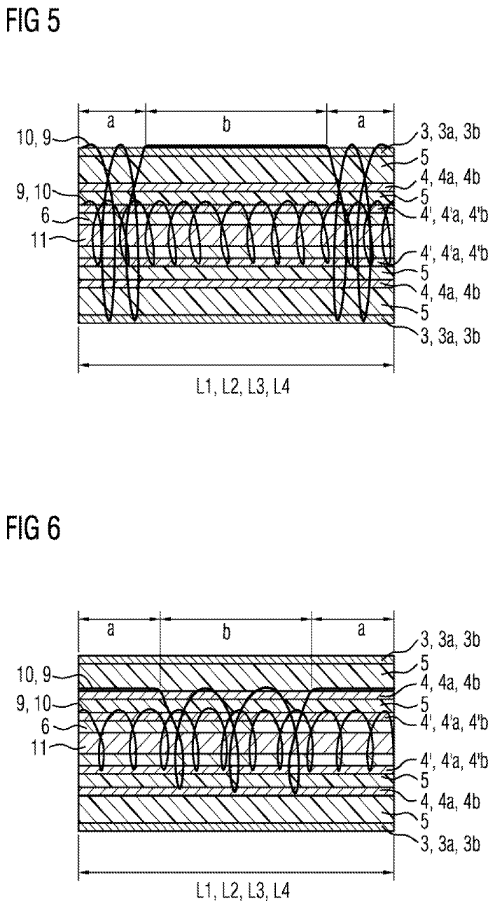

In the following, FIGS. 5 to 7 show schematic representations of a position sensor system according to FIG. 4 in longitudinal section. In this case, as a departure from the representations in FIGS. 1 to 4, the excitation coil 9 and the sensor coil 10 are shown as coils with round windings for better spatial illustration.

The multilayer circuit board 2 has a length L1, the excitation coil 9 has a length L2, the sensor coil 10 has a length L3 and the soft magnetic core 11 has a length L4. The lengths L1, L2, L3 and L4 are respectively divided into outer sections a and an inner section b.

The lengths L2, L3 and L4 can assume 2 different values within the maximum value L1 of the multilayer circuit board.

The windings of the excitation coil 9 and/or of the sensor coil 10 may be distributed uniformly, for example equidistantly, over the corresponding length L2, L3.

The windings of the excitation coil 9 and/or of the sensor coil 10 may however also be distributed non-uniformly over the corresponding length L2, L3.

In this case, the windings of the excitation coil 9 and/or of the sensor coil 10 may be arranged predominantly on an outer section a or on an inner section b.

In FIG. 5, in conjunction with FIG. 2, a winding of the excitation coil 9 is formed by second outer conductor tracks 3b and second through-hole 8, wherein the windings in the two outer sections a of the length L2 of the excitation coil 9 are arranged symmetrically in relation to the core 11.

A winding of the sensor coil 10 is formed by second inner conductor tracks 4′a and corresponding sections of the first through-hole 7, where the windings are arranged symmetrically in relation to the core 11, distributed uniformly over the entire length L3 of the sensor coil 10.

Here, the excitation coil 9 encloses the sensor coil 10. The excitation coil 9 and the sensor coil 10 could also be interchanged.

In FIG. 6, in conjunction with FIG. 2, as in FIG. 5, a winding of the sensor coil 10 is formed by second inner conductor tracks 4′a and corresponding sections of the first through-hole 7, wherein the windings are arranged symmetrically in relation to the core 11, distributed uniformly over the entire length L3 of the sensor coil 10.

As a departure from FIG. 5, a winding of the excitation coil 9 is formed here by second outer conductor tracks 4b on the inner copper layer 4 and corresponding sections of the second through-hole 8, where the windings in the inner section b of the length L2 of the excitation coil 9 are arranged symmetrically in relation to the core 11, for example distributed uniformly.

Here, too, the excitation coil 9 encloses the sensor coil 10. The excitation coil 9 and the sensor coil 10 may also be interchanged.

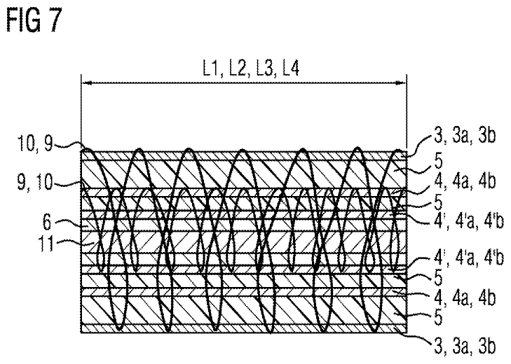

In FIG. 7, in conjunction with FIG. 2, a winding of the excitation coil 9 is formed by second outer conductor tracks 3b and second through-hole 8, where the windings are arranged symmetrically in relation to the core 11, distributed uniformly over the entire length L2 of the excitation coil 9.

A winding of the sensor coil 10 is formed by a first inner conductor track 4a, a first inner conductor track 4′a and corresponding sections of the first through-hole 7, wherein the windings are distributed uniformly over the entire length L3 of the sensor coil 10. This example represents an asymmetrical arrangement of a winding with respect to the layer of the multilayer printed circuit board 2.

Here, too, the excitation coil 9 encloses the sensor coil 10. The excitation coil 9 and the sensor coil 10 may also be interchanged, depending on the application.

It would also be conceivable for a layer of the multilayer printed circuit board 2 to change from winding to winding.

A number of implementations have been described. Nevertheless, it will be understood that various modifications may be made without departing from the spirit and scope of the disclosure. Accordingly, other implementations are within the scope of the following claims.

What is claimed is:

1. A magnetic position sensor system comprising:
a multilayer circuit board having layer, the multilayer circuit board includes:
an insulator layer;
at least one copper layer, the at least one copper layer comprises at least a first conductor track and/or a second conductor track;
a first through-hole;
a second through-hole;
a circuit board core; and
a sensor having a soft magnetic core, an excitation coil with at least one excitation winding and a sensor coil with at least one sensor winding;
wherein the soft magnetic core is arranged in the circuit board core of the multilayer circuit board, and is surrounded by an excitation coil and a sensor coil,
wherein an excitation winding of the excitation coil comprises two first through-holes, at least in sections, and two first conductor tracks, and
wherein a sensor winding of the sensor coil comprises two second through-holes, at least in sections, and two second conductor tracks.

2. The magnetic position sensor system as claimed in claim 1, wherein the excitation coil and the sensor coil are arranged on different layers of the multilayer circuit board.

3. The magnetic position sensor system as claimed in claim 1, wherein the excitation coil and the sensor coil are arranged on the same layer of the multilayer circuit board.

4. The magnetic position sensor system as claimed in claim 3, wherein the excitation winding comprises two first through-holes and two first conductor tracks on an outer copper layer, and wherein the sensor winding comprises two second through-holes and two second conductor tracks on the outer copper layer.

5. The magnetic position sensor system as claimed in claim 1, wherein the multilayer circuit board has a multilayer circuit board length, the excitation coil has a excitation coil length, the sensor coil has a sensor coil length and the core has a core length, wherein the multilayer circuit board length, the excitation coil length, the sensor coil length, and the core length are respectively divided into outer sections and inner sections.

6. The magnetic position sensor system as claimed in claim 1, wherein the windings of the excitation coil and/or of the sensor coil are distributed uniformly over their corresponding length.

7. The magnetic position sensor system as claimed in claim 1, wherein the windings of the excitation coil and/or of the sensor coil are distributed non-uniformly over their corresponding length.

8. The magnetic position sensor system as claimed in claim 7, wherein the windings of the excitation coil and/or of the sensor coil are arranged predominantly on an outer section.

9. The magnetic position sensor system as claimed in claim 7, wherein the windings of the excitation coil and/or of the sensor coil are arranged predominantly on an inner section.

10. The magnetic position sensor system (1) as claimed in claim 1, wherein the excitation coil encloses the sensor coil in sections or entirely.

11. The magnetic position sensor system as claimed in claim 1, wherein the sensor coil encloses the excitation coil in sections or entirely.

12. The magnetic position sensor system as claimed in claim 1, wherein the windings of the excitation coil and/or of the sensor coil are arranged symmetrically in relation to the core.

13. The magnetic position sensor system as claimed in claim 1, wherein the windings of the excitation coil and/or of the sensor coil are arranged asymmetrically in relation to the core.

14. The magnetic position sensor system as claimed in claim 1, wherein the core is of a strip-shaped form.

15. A sensor module comprising:
at least one position sensor system; and
at least parts of an electronic evaluating unit,
wherein the at least one position sensor system comprises:
a multilayer circuit board having layer, the multilayer circuit board includes:
an insulator layer;
at least one copper layer, the at least one copper layer comprises at least a first conductor track and/or a second conductor track;
a first through-hole;
a second through-hole;
a circuit board core; and
a sensor having a soft magnetic core, an excitation coil with at least one excitation winding and a sensor coil with at least one sensor winding;
wherein the soft magnetic core is arranged in the circuit board core of the multilayer circuit board, and is surrounded by an excitation coil and a sensor coil,
wherein an excitation winding of the excitation coil comprises two first through-holes, at least in sections, and two first conductor tracks, and
wherein a sensor winding of the sensor coil comprises two second through-holes, at least in sections, and two second conductor tracks.

16. The sensor module as claimed in claim 15, wherein the electronic evaluating unit is arranged at least partially in, on or outside the multilayer circuit board.

17. A control device comprising a sensor module, the sensor module comprising:
at least one position sensor system; and
at least parts of an electronic evaluating unit,
wherein the at least one position sensor system comprises:
a multilayer circuit board having layer, the multilayer circuit board includes:
an insulator layer;
at least one copper layer, the at least one copper layer comprises at least a first conductor track and/or a second conductor track;
a first through-hole;
a second through-hole;
a circuit board core; and
a sensor having a soft magnetic core, an excitation coil with at least one excitation winding and a sensor coil with at least one sensor winding;
wherein the soft magnetic core is arranged in the circuit board core of the multilayer circuit board, and is surrounded by an excitation coil and a sensor coil,
wherein an excitation winding of the excitation coil comprises two first through-holes, at least in sections, and two first conductor tracks, and
wherein a sensor winding of the sensor coil comprises two second through-holes, at least in sections, and two second conductor tracks.
